(19) United States
(12) Patent Application Publication
(10) Pub. No.: US 2025/0014995 A1
(43) Pub. Date: Jan. 9, 2025

(54) SEMICONDUCTOR DEVICES

(71) Applicant: Samsung Electronics Co., Ltd., Suwon-si (KR)

(72) Inventors: Jinwoo LEE, Suwon-si (KR); Hojun CHOI, Suwon-si (KR); Sutae KIM, Suwon-si (KR); Hyelim KIM, Suwon-si (KR); Seung CHOI, Suwon-si (KR)

(73) Assignee: Samsung Electronics Co., Ltd., Suwon-si (KR)

(21) Appl. No.: 18/663,381

(22) Filed: May 14, 2024

(30) Foreign Application Priority Data
Jul. 6, 2023 (KR) 10-2023-0087758

(51) Int. Cl. H01L 23/528; H01L 23/522; H01L 29/06; H01L 29/417; H01L 29/423; H01L 29/66; H01L 29/775; H01L 29/786

(52) U.S. Cl. CPC H01L 23/5283; H01L 23/5226; H01L 29/0673; H01L 29/41733; H01L 29/41775; H01L 29/42392; H01L 29/66545; H01L 29/775; H01L 29/78696

(57) ABSTRACT

A semiconductor device includes a plurality of active patterns respectively extending on a substrate in a first direction, a separation pattern extending on the substrate in a second direction, and dividing each of the plurality of active patterns into first and second active patterns, the separation pattern including a first separation pattern and a second separation pattern, the second separation pattern being shifted from the first separation pattern in the first direction to partially overlap the first separation pattern in the second direction, first and second dummy gate structures on first and second sides of the separation pattern, respectively, and extending along corresponding end portions of the first and second active patterns in the second direction, respectively, and a plurality of first and second gate structures crossing portions of the first and second active patterns, respectively, and extending in the second direction.

### CROSS-REFERENCE TO RELATED APPLICATION(S)

This application claims the benefit under 35 USC 119(a) of Korean Patent Application No. 10-2023-0087758 filed on Jul. 6, 2023 in the Korean Intellectual Property Office, the entire disclosure of which is incorporated herein by reference for all purposes.

### BACKGROUND

The present inventive concepts relate to semiconductor devices.

In various semiconductor devices such as logic circuits and memories, active regions such as source and drain regions are connected to a metal wiring of a Back End Of Line (BEOL) through contact structures. There is a need for a method of disposing at least some wiring (e.g., power lines) of the BEOL is disposed on the backside of the substrate and forming a conductive through-structure penetrating through the semiconductor substrate, for connection to some wirings.

### SUMMARY

Some example embodiments of the present inventive concepts provide semiconductor devices having improved reliability.

According to an example embodiment, a semiconductor device includes a substrate having a first surface and a second surface opposing each other, a plurality of active patterns respectively extending in a first direction on the first surface of the substrate, a separation pattern extending in a second direction on the first surface of the substrate, the second direction intersecting the first direction, the separation pattern dividing each of the plurality of active patterns into first and second active patterns, the separation pattern including a first separation pattern and a second separation pattern shifted from the first separation pattern in the first direction to partially overlap the first separation pattern in the second direction, a first dummy gate structure and a second dummy gate structure on both sides of the separation pattern, respectively, the first and second dummy gate structures extending along corresponding end portions of the first and second active patterns in the second direction, respectively, a plurality of first gate structures and a plurality of second gate structures crossing the first and second active patterns, respectively, the plurality of first and second gate structures extending in the second direction, source/drain patterns on both sides of each of the plurality of first and second gate structures and on the first and second active patterns, an interlayer insulating layer on the substrate and covering the source/drain patterns, a contact structure penetrating through the interlayer insulating layer and connected to at least one of the source/drain patterns, a plurality of buried conductive structures in the separation pattern and arranged in the second direction, at least one of the plurality of buried conductive structures penetrating through the interlayer insulating layer and electrically connected to the contact structure, and a plurality of power transmission structures extending from the second surface of the substrate toward the first surface, the plurality of conductive through-structures connected to the plurality of buried conductive structures, respectively.

According to an example embodiment, a semiconductor device includes a plurality of active patterns respectively extending on a substrate in a first direction, a separation pattern extending on the substrate in a second direction, the second direction intersecting the first direction, the separation pattern dividing each of the plurality of active patterns into a first active pattern and a second active pattern, the separation pattern including a plurality of first separation patterns and a plurality of second separation patterns alternating with each other, the plurality of second separation patterns being shifted from the plurality of first separation patterns in the first direction to partially overlap the plurality of first separation patterns in the second direction, a first dummy gate structure and a second dummy gate structure on both sides of the separation pattern, respectively, the first and second dummy gate structures extending along corresponding end portions of the first and second active patterns in the second direction, respectively, a plurality of first and second gate structures crossing the first and second active patterns, respectively, the first and second gate structures extending in the second direction, source/drain patterns on both sides of each of the plurality of first and second gate structures and on the first and second active patterns, an interlayer insulating layer on the substrate and covering the source/drain patterns, a contact structure penetrating through the interlayer insulating layer and connected to at least one of the source/drain patterns, a plurality of buried conductive structures in the separation pattern and arranged in the second direction, at least one of the plurality of buried conductive structures penetrating through the interlayer insulating layer and electrically connected to the contact structure, a plurality of conductive through-structures extending from a lower surface of the substrate toward an upper surface of the substrate, the plurality of conductive through-structures connected to the plurality of buried conductive structures, respectively, and a first interconnection structure on the interlayer insulating layer, the a first interconnection structure including a first interconnection layer connecting the contact structure and the buried conductive structures.

According to an example embodiment, a semiconductor device includes a plurality of active patterns respectively extending on a substrate in a first direction, a separation pattern extending on the substrate in a second direction, the second direction intersecting the first direction, the separation pattern dividing each of the plurality of active patterns into a first active pattern and a second active pattern, the separation pattern including a plurality of first separation patterns and a plurality of second separation patterns alternating with each other in the second direction, the plurality of second separation patterns being shifted from the plurality of first separation patterns in the first direction to partially overlap the plurality of first separation patterns in the second direction, a first dummy gate structure and a second dummy gate structure on first and second sides of the separation pattern, respectively, the first and second dummy gate structures extending along corresponding end portions of the first and second active patterns in the second direction, respectively, and a plurality of first and second gate structures extending in the second direction and crossing the first and second active patterns, respectively, and extending in the second direction. The first dummy gate structure on a first side of each of the plurality of first separation patterns is connected to a corresponding one of a plurality of first gate structures on a first side of adjacent second separation patterns among the plurality of second separation patterns, and the second dummy gate structure on a second side of each of the plurality of second separation patterns is connected to a corresponding one of a plurality of second gate structures on a second side of adjacent first separation patterns among the plurality of first separation patterns.

### BRIEF DESCRIPTION OF DRAWINGS

The above and other aspects, features, and advantages of the present inventive concepts will be more clearly understood from the following detailed description, taken in conjunction with the accompanying drawings, in which:

FIG. 1 is a plan view illustrating a semiconductor device according to an example embodiment;

FIGS. 2A and 2B are cross-sectional views of the semiconductor device illustrated in FIG. 1 taken along lines I1-I1′ and I2-I2′, respectively;

FIGS. 3A and 3B are cross-sectional views of the semiconductor device illustrated in FIG. 1, taken along lines II1-II1′ and II2-II2′, respectively;

FIG. 4 is a plan view illustrating a semiconductor device according to an example embodiment;

FIGS. 5A and 5B are cross-sectional views of the semiconductor device illustrated in FIG. 4, taken along lines I1-I1′ and I2-I2′, respectively;

FIGS. 6 and 7 are plan views illustrating semiconductor devices according to some example embodiments, respectively;

FIG. 8 is a plan view illustrating a semiconductor device according to an example embodiment;

FIGS. 9A and 9B are cross-sectional views of the semiconductor device illustrated in FIG. 9, taken along lines I1-I1′ and I2-I2′, respectively; and

FIGS. 10A and 10B are cross-sectional views of the semiconductor device illustrated in FIG. 9, taken along lines II1-II1′ and II2-II2′, respectively.

### DETAILED DESCRIPTION

Hereinafter, some example embodiments will be described with reference to the accompanying drawings.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

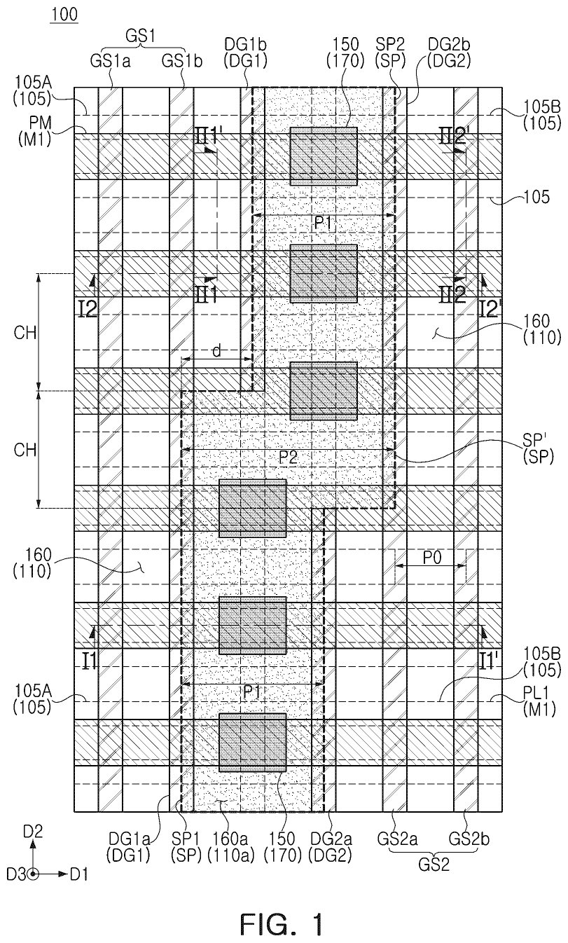

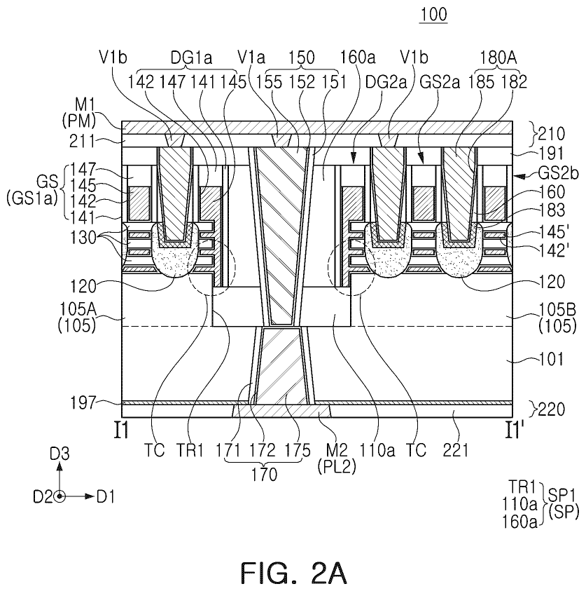

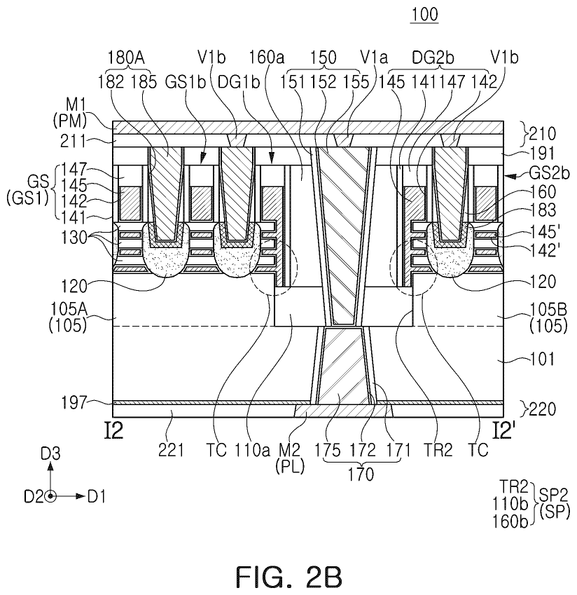

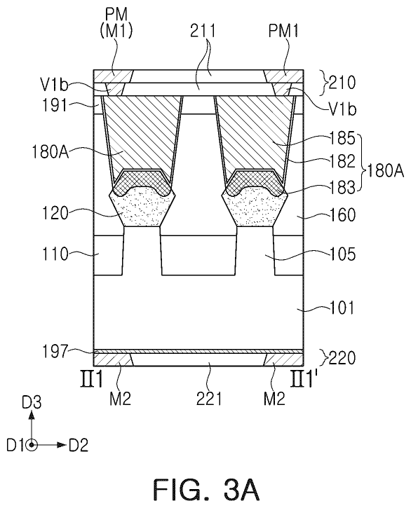

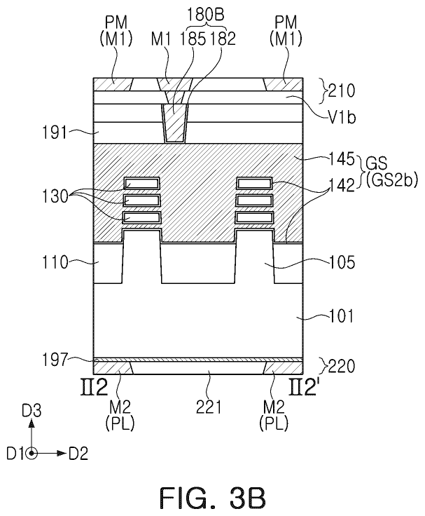

FIG. 1 is a plan view illustrating a semiconductor device according to an example embodiment, FIGS. 2A and 2B are cross-sectional views of the semiconductor device illustrated in FIG. 1 taken along lines I1-I1′ and I2-I2′, respectively, and FIGS. 3A and 3B are cross-sectional views of the semiconductor device illustrated in FIG. 1 taken along lines II1-II1′ and II2-II2′, respectively.

Referring to FIGS. 1, 2A, 2B, 3A, and 3B, a semiconductor device 100 according to this embodiment includes a substrate 101 having a first side and a second side located opposite to each other, a plurality of active patterns 105 extending from the first surface (or active area) of the substrate 101 in a first direction (e.g., D1 direction), a separation pattern (SP) extending in a second direction (e.g., D2 direction) intersecting the first direction (e.g., D1 direction) and dividing each of the plurality of active patterns 105 into first and second active patterns 105A and 105B, and first and second dummy gate structures (DG1, DG2) extending in the second direction (e.g., D2 direction) along the ends of the plurality of first and second active patterns 105 on both sides of the separation pattern SP.

In this case, the gate structures GS1 and GS2 refer to the ‘active gate structures’ that make up the transistor. The dummy gate structures DG1 and DG2 refer to ‘inactive gate structures’ that do not constitute a transistor.

The semiconductor device 100 according to this embodiment may further include first and second gate structures GS1 and GS2 crossing the first and second active patterns 105A and 105B, respectively, and extending in the second direction (e.g., direction D2), source/drain patterns 120 disposed on the first and second active patterns 105A and 105B on both sides of the first and second gate structures GS1 and GS2, first contact structures 180A connected to the source/drain patterns 120, and second contact structures 180B connected to the first and second gate structures GS1 and GS2.

The substrate 101 may include, for example, a semiconductor such as Si or Ge, or a compound semiconductor such as SiGe, SiC, GaAs, InAs, or InP. In another example, the substrate 101 may have a silicon on insulator (SOI) structure. An active region having a well doped with impurities is disposed on the first side of the substrate 101, and the active pattern 105 may have a protruding fin-shaped structure extending in a first direction (e.g., D1 direction) on the active area. However, the present inventive concepts are not limited thereto, and the active region and active pattern 105 may be an N-type region for a P-MOS transistor or a P-type region for an N-MOS transistor.

The device isolation layer 110 may be disposed on the substrate 101 to define an active area including the active pattern 105. For example, the device isolation layer 110 may include silicon oxide or a silicon oxide-based insulating material. The device isolation layer 110 may be a shallow trench isolation (STI) that defines the active pattern 105.

Referring to FIGS. 1, 2A, and 2B, the active pattern 105 extends from the first surface of the substrate 101 in the first direction (e.g., D1 direction), and has a fin-shaped structure protruding from the upper surface of the active area. A plurality of channel layers 130 (or semiconductor patterns) may be arranged on the active pattern 105 to be spaced apart from each other in a third direction (e.g., D3 direction) perpendicular to the first surface of the substrate 101. The active pattern 105 and the plurality of channel layers 130 may be provided as a multi-channel layer of the transistor. In this example embodiment, the plurality of channel layers 130 is illustrated as three, but the number thereof is not particularly limited. For example, the plurality of channel layers 130 may include silicon (Si), silicon germanium (SiGe), or germanium (Ge). In some example embodiments, the plurality of channel layers 130 may include the same semiconductor as the substrate 101.

As illustrated in FIG. 1, the semiconductor device 100 according to this example embodiment may include a plurality of gate structures GS extending in the second direction (e.g., direction D2). As described above, the plurality of gate structures GS may include first and second gate structures GS1a, GS1b, GS2a, and GS2b crossing the first and second active patterns 105, respectively.

As illustrated in FIGS. 2A and 2B, the first and second gate structures GS1a, G1b and GS2a and GS2b may respectively include gate spacers 141, a gate insulating film 142 and a gate electrode 145 sequentially disposed between the gate spacers 141, and a gate capping layer 147 disposed on the gate electrode 145. For example, the gate spacers 141 may include an insulating material such as SiOCN, SiON, SiCN, or SiN. The gate insulating layer 142 may be made of, for example, a silicon oxide layer, a high-x dielectric layer, or combinations thereof. The high-x dielectric layer may include a material with a higher dielectric constant (e.g., about 10 to 25) than the silicon oxide layer. For example, the high-x dielectric film may include a material selected from the group consisting of hafnium oxide, hafnium oxynitride, hafnium silicon oxide, lanthanum oxide, lanthanum aluminum oxide and combinations thereof, but is not limited thereto. The gate electrode 145 may include a conductive material, and for example, may include a metal nitride such as titanium nitride (TiN), tantalum nitride (TaN), or tungsten nitride (WN), and/or a metallic material such as aluminum (Al), tungsten (W), or molybdenum (Mo) or a semiconductor material such as doped polysilicon. In some example embodiments, a gate electrode 145 may be a multilayer structure including two or more films. Additionally, the gate capping layer 147 may include, for example, silicon nitride, silicon oxynitride, silicon carbonitride, or silicon oxycarbonitride.

The separation pattern SP may provide two separated cell regions on the substrate 101 by dividing each of the plurality of active patterns 105 into first and second active patterns 105A and 105B.

As illustrated in FIG. 1, the separation pattern (SP) employed in this example embodiment may include a first separation pattern (SP1) extending in a second direction (e.g., D2 direction), and a second separation pattern (SP2) shifted from the first separation pattern (SP1) in the first direction (e.g., D1 direction) to partially overlap the first separation pattern (SP1) in the second direction (e.g., D2 direction). As such, the separation pattern SP employed in this example embodiment extends overall in the second direction (e.g., D2 direction), but has a pattern (e.g., a portion) that is partially shifted in the first direction (e.g., D1 direction).

Referring to FIGS. 2A and 2B, the separation pattern SP employed in this example embodiment includes first and second trenches TR1 and TR2 having a depth equal to or lower than that of the active pattern 105. In this embodiment, each of the first and second trenches TR1 and TR2 may have a depth corresponding to the depth of the STI defining the active pattern. The first and second trenches TR1 and TR2 may be shifted with respect to each other in a first direction (e.g., D1 direction) to define first and second separation patterns SP1 and SP2, respectively.

The separation pattern (SP1) employed in this example embodiment may include a portion of the device isolation layer 110 partially filled in each of the first and second trenches TR1 and TR2, and an interlayer insulating layer 160 disposed on the device isolation layer 110. Portions of the device isolation layer 110 filled in the first and second trenches TR1 and TR2 may have the same level as the other device isolation layers 110.

In this example embodiment, the separation pattern SP has a partially shifted pattern, and each of the first and second dummy gate structures DG1 and DG2 located on both sides (i.e., the first side and the second side) of the separation pattern SP may be disconnected. As illustrated in FIG. 1, the first dummy gate structure DG1 may be disconnected by being divided into a first dummy gate portion (DG1a) on the first side of the first separation pattern (SP1) and a second dummy gate portion DG1b on the first side of the second separation pattern SP2. Similarly, the second dummy gate structure DG2 may be disconnected by being divided into a second dummy gate portion DG2a on the second side of the first separation pattern SP1 and a second dummy gate portion DG2b on the second side of the second separation pattern SP2.

The first and second dummy gate structures DG1 and DG2 are formed along the ends of the first and second active patterns 105A and 105B, respectively, as illustrated in FIGS. 2A and 2B, and may thus have structurally unstable conditions unlike the first and second gate structures GS1 and GS2.

Unlike the present example embodiment, when these vulnerable dummy gate structures are located on both sides of the separation pattern extended without being shifted (e.g., without including a portion shifted from another portion), due to a relatively long length thereof, the structural vulnerability thereof may increase. Thus, bending and leaning defects may easily occur in relatively long dummy gate structures.

However, as described above, the first and second dummy gate structures DG1 and DG2 employed in this example embodiment are disconnected by the shifting of the separation pattern SP (e.g., by shifting one of the first and second separation patterns SP1 and SP2 from the other one of the first and second separation patterns SP1 and SP2), the lengths of the first and second dummy gate structures DG1 and DG2 in the second direction (e.g., direction D2) may be shortened. Thus, structural defects such as leaning defects described above may be significantly alleviated.

The length of the first and second separation patterns SP1 and SP2 in the second direction (e.g., D2 direction) may correspond to an integer multiple of the cell height CH. In this case, the cell height (CH) may be defined as (or may be equal to) the length of each logic cell in the second direction (e.g., D2 direction). In this case, ‘logic cells’ may respectively include first and second active regions (e.g., 2 active patterns adjacent in the second direction) arranged in a second direction (e.g., D2 direction) between upper and lower boundaries (boundaries with other cells arranged in the second direction). In this case, the cell height (CH) may be defined as the distance between its upper and lower boundaries.

To effectively reduce leaning defects, the length of each of the first and second separation patterns SP1 and SP2 in the second direction (e.g., D2 direction) may be designed with a maximum of 2 to 4 cell heights (CH) (e.g., 2CH). In some example embodiments, the length of each of the first and second separation patterns SP1 and SP2 in the second direction (e.g., D2 direction) may be 1 m or less (e.g., 900 nm or less).

The first gate structures (GS1a, GS1b) and the first dummy gate portions (DG1a, DG1b) may be arranged at a constant pitch P0 (hereinafter referred to as ‘gate pitch’) in the first direction (e.g., D1 direction). Similarly, the second gate structures GS2a and GS2b and the second dummy gate portions DG2a and DG2b may be arranged at the same pitch P0 in the first direction (e.g., D1 direction).

The separation pattern SP may have a width corresponding to an integer multiple of the gate pitch P0. In this embodiment, the width P1 of each of the first and second separation patterns SP1 and SP2 may be twice the gate pitch P0. The first and second separation patterns SP1 and SP2 have the same width. In some example embodiments, the first and second separation patterns SP1 and SP2 may have different widths.

The distance d shifted from the first separation pattern SP1 to the first direction (e.g., D1 direction) of the second separation pattern SP2 may be an integer multiple of the gate pitch P0. In this example embodiment, the shifted distance d may be a distance corresponding to (e.g., may be equal to) the gate pitch P0. In some example embodiments, the shifted distance d may be smaller than the width P1 of the separation pattern SP.

The separation pattern SP may have a connection separation pattern SP′ provided as an area shifted between the first and second separation patterns SP1 and SP2. The connection separation pattern (SP′) may have a width overlapping with each of the first and second separation patterns (SP1, SP2) in the second direction (e.g., D2 direction) between the first and second separation patterns (SP1, SP2), and the connection separation pattern SP′ may have a width P2 greater than each width P1 of the first and second separation patterns.

In this example embodiment, as illustrated in FIG. 1, the width P2 of the connection separation pattern SP′ may have a width defined by (e.g., a width equal to) the pitch between the first dummy gate portion DG1a on the first side of the first separation pattern SP1 and the second dummy gate portion DG2b on the second side of the second separation pattern SP2. For example, the width P2 of the connection separation pattern SP′ may be three times the gate pitch P0. The length of the connection separation pattern SP′ in the second direction (e.g., D2 direction) may be an integer multiple of the cell height CH. In this example embodiment, the length of the connection separation pattern SP′ in the second direction (e.g., D2 direction) may be one cell height CH.

As described above, the first and second dummy gate structures DG1 and DG2 employed in this example embodiment are disconnected by the shift of the separation pattern SP, and may have a shortened length in the second direction (e.g., D2 direction). In this example embodiment, the dummy gate portions DG1b and DG2a on both sides of the separation pattern SP are disconnected, or among the plurality of gate structures GS1 and GS2, the gate structures GS1b and GS2a may be connected to the separation pattern SP.

Referring to FIGS. 1, 2A and 2B, the second dummy gate portion DG2a on the second side of the first separation pattern SP1 is cut off by the shifted separation pattern portion (e.g., the connection separation pattern SP′), and the first dummy gate portion DG1b on the first side of the second separation pattern SP2 is cut off by the shifted separation pattern portion (e.g., the connection separation pattern SP′). On the other hand, the first dummy gate portion DG1a on the first side of the first separation pattern SP1 extends in a second direction (e.g., D2 direction) and serves as the first gate structure GS1b, and the second dummy gate portion DG2b on the second side of the second separation pattern SP2 may extend in a second direction (e.g., D2 direction) and serve as the second gate structure GS2a.

The semiconductor device 100 according to this example embodiment is arranged according to a separation pattern (SP) and includes power transmission structures for supplying power to each logic cell from the backside of the substrate 101. The power transmission structures employed in this example embodiment includes a buried conductive structure 150 arranged in the second direction (e.g., D2 direction) in the separation pattern SP, and conductive through-structures 170 extending from the second side of the substrate 101 toward the first side and connected to the buried conductive structure 150.

In this example embodiment, as illustrated in FIGS. 2A and 2B, the buried conductive structures 150 extend to the first side of the substrate 101, and the power transmission structures 170 may penetrate the substrate 101 and contact the bottom surfaces of the buried conductive structures 150 on the first side of the substrate 101, respectively.

Each of the conductive through-structures 170 receives power from the backside power line PL2 (or the second power line) located on the second side of the substrate 101. Power may be supplied to the source/drain pattern 120 of each logic cell through the buried conductive structures 150. In this example embodiment, the buried conductive structures 150 may be electrically connected to the source/drain patterns 120 through the front-side power line (PM) (or first power line) of the first interconnection structure 210.

Referring to FIG. 1, in this example embodiment, the buried conductive structures 150 and the conductive through-structures 170 may be arranged at a pitch corresponding to (e.g., a pitch equal to) the cell height (CH) of the logic cells in the separation pattern (SP). As such, in this example embodiment, the buried conductive structures 150 and the conductive through-structures 170 are disposed at the upper and lower boundaries of each logic cell and may serve as power transmission structures for each logic cell.

Buried conductive structures 150 may include first buried conductive structures arranged in a second direction (e.g., D2 direction) in the first separation pattern SP1, and second buried conductive structures arranged in a second direction (e.g., D2 direction) in the second separation pattern SP2. The arrangement of the second buried conductive structures may be shifted by a distance d corresponding to the gate pitch P0 in the first direction (e.g., D1 direction) from the arrangement of the first buried conductive structures, similar to the shift of the first and second separation patterns (SP1, SP2).

In this example embodiment, the buried conductive structure 150 between the first and second separation patterns SP1 and SP2 may be provided as a power transmission structure that supplies power to cells overlapping in the first direction (e.g., D1 direction) of the connection separation pattern SP1. In this case, the length of the connection separation pattern (SP′) in the second direction (e.g., D2 direction) may be defined by (e.g., may be equal to) the pitch of adjacent buried conductive structures 150 between the first and second separation patterns SP1 and SP2.

The buried conductive structure 150 may include a first conductive material 155.

A first conductive barrier 152 surrounding the bottom and side surfaces of the first conductive material 155. In this example embodiment, the buried conductive structure 150 may further include a first insulating liner 151 surrounding the first conductive barrier 152. The conductive through-structure 170 may include a second conductive material 175, a second insulating liner 251 disposed between the substrate 101 and a second conductive barrier 172 surrounding the bottom and side surfaces of the second conductive material 175.

For example, the first and second conductive materials 155 and 1755 may include Cu, Co, Mo, Ru, W, or alloys thereof. In some example embodiments, the first and second conductive materials 155 and 175 may include different conductive materials. For example, the first conductive material 155 may include W or Mo, and the second conductive material 175 may include Cu. For example, the first and second conductive barriers 152 and 172 may include Ta, TaN, Mn, MnN, WN, Ti, TiN, or combinations thereof. For example, the first and second insulating liners 151 and 171 may include SiO₂, SiN, SiCN, SiC, SiCOH, SiON, Al₂O₃, AlN, or combinations thereof.

In this example embodiment, the first and second dummy gate structures DG1 and DG2 located on both sides of the separation pattern SP may also have a similar configuration to the gate structure GS. Each of the first and second dummy gate structures DG1 and DG2 may include gate spacers 141, a gate insulating film 142, a gate electrode 145, and a gate capping layer 147. However, as described above, the first and second dummy gate structures DG1 and DG2 are located at the ends of the first and second active patterns 105A and 105B, and as illustrated in FIGS. 2A and 2B, some areas of the first and second dummy gate structures DG1 and DG2 may extend to the device isolation layer 110 along the cross-sections of the first and second active patterns 105A and 105B.

As such, the first and second dummy gate structures DG1 and DG2 have an asymmetric structure along the ends of the first and second active patterns 105A and 105B, and thus are structurally unstable compared to the first and second gate structures GS1 and GS2, and to reduce leaning defects caused thereby, by using the shift of the separation pattern SP employed in this example embodiment, the lengths of the first and second dummy gate structures DG1 and DG2 in the second direction (e.g., D2 direction) may be shortened, and thus, structural defects such as leaning defects may be significantly reduced.

The source/drain patterns 120 may be disposed on areas of the first and second active patterns 105 located on both sides of the first and second gate structures GS1 and GS2. The source/drain patterns 110 may be respectively connected to both ends of the plurality of channel layers 130 in the first direction (e.g., D1 direction). The gate electrode 145 may have a portion 145′ extending in a second direction (e.g., D2 direction) to surround the plurality of channel layers 130 and intersect the first and second active patterns 105. The gate insulating layer 142 may also have a portion 142′ extending between the plurality of channel layers 130 and the gate electrode portion 145′. In this manner, the semiconductor device 100 according to this example embodiment may configure a gate-all-around type field effect transistor.

The source/drain pattern 120 may include an epitaxial pattern provided by selective epitaxial growth (SEG) from the recessed surfaces of the first and second active patterns 105A and 105B and the side surfaces of the plurality of channel layers 130 on both sides of the first and second gate structures GS1 and GS2. This source/drain pattern 120 is also called raised source/drain (RSD). For example, the source/drain pattern 120 may be Si, SiGe, or Ge, and may have a conductivity type of either N-type or P-type. When forming the P-type source/drain region 110, re-growth with SiGe is performed, and for example, boron (B), indium (In), gallium (Ga), boron trifluoride (BF3), or the like may be doped as P-type impurities. When the N-type source/drain region 110 is formed of silicon (Si), as N-type impurities, for example, phosphorus (P), nitrogen (N), arsenic (As), antimony (Sb), or the like may be doped. During the growth process, the source/drain pattern may have different shapes along the crystallographically stable plane. For example, the source/drain pattern 120 may have a pentagonal cross-section (in the case of P-type), and may have a hexagonal or polygonal cross-section with gentle angles (in the case of N-type).

The semiconductor device 100 according to this example embodiment may include an interlayer insulating layer 160 disposed on the device isolation layer 110. The interlayer insulating layer 160 may be disposed around the source/drain pattern 120 and the first and second gate structures GS. For example, the interlayer insulating layer 160 may be Flowable Oxide (FOX), Tonen SilaZen (TOSZ), Undoped Silica Glass (USG), Borosilica Glass (BSG), PhosphoSilaca Glass (PSG), BoroPhosphoSilica Glass (BPSG), Plasma Enhanced Tetra Ethyl Ortho Silicate (PETEOS), Fluoride Silicate Glass (FSG), High Density Plasma (HDP) oxide, Plasma Enhanced Oxide (PEOX), Flowable CVD (FCVD) oxide, or combinations thereof. The interlayer insulating layer 160 may be formed using a chemical vapor deposition (CVD) process, a flowable CVD process, or a spin coating process. The semiconductor device 100 according to this example embodiment may further include an intermediate insulating layer 191 covering the first and second gate structures GS1 and GS2 on the interlayer insulating layer 160. The middle insulating layer 191 may include an insulating material similar to the interlayer insulating layer 160

FIGS. 2A and 2B and 3A and 3B, the first and second contact structures 180A and 180B penetrate the interlayer insulating layer 160 and the intermediate insulating layer 191, and may be connected to the source/drain pattern 120 and the gate electrode 145, respectively. Each of the first and second contact structures 180A and 180B may include a conductive barrier 182 and a contact plug 185. For example, the contact plug 185 may include Cu, Co, Mo, Ru, W, or an alloy thereof. Additionally, the conductive barrier 182 may include Ta, TaN, Mn, MnN, WN, Ti, TiN, or combinations thereof. In this embodiment, each of the first contact structures 180A may include a metal silicide film 183 formed on the source/drain patterns 120 to improve contact resistance.

In this example embodiment, the first interconnection structure 210 may include a plurality (e.g., two) of first insulating layers 211 and first metal lines M1 and first metal vias V1a, V1b, and V1c formed on the first insulating layer 211. For example, the first interconnection layer including the first metal lines M1 and the first metal vias V1a, V1b, and V1c may be formed through a dual damascene process.

At least one of the first contact structures 180A may be connected to the first metal line M1 through the metal via V1b. As described above, the first metal line M1 may be connected to the buried conductive structure 150 through the metal via V1a and may be provided as the first power line PM.

An insulating protective film 197 may be disposed on the second surface of the substrate 101. The insulating protective film 197 may be provided to surround the contact area of the buried conductive structure 150B protruding from the second surface of the substrate 101. A second interconnection structure 220 is disposed on the insulating protective film 197. The second interconnection structure 220 may include a second insulating layer 221 and a second metal line M2 formed on the second insulating layer 221. The second metal line M2 may include a second power line PL connected to the conductive through via 170. The insulating protective film 197 and the first and second insulating layers 211 and 221 may include different insulating materials. For example, the insulating protective film 271 may include AlN or SiN, and the first and second insulating layers 211 and 221 may include SiO2.

According to the above-described example embodiment, by shifting a portion of the separation pattern SP in which the power transmission structures 150 and 170 are arranged to an integer multiple (e.g., 1 times) of the gate pitch (P0) in the first direction (e.g., D1 direction) and by shortening the length of the first and second dummy gate structures (DG1, DG2) adjacent to the separation pattern (SP), the structural vulnerability (e.g., lean risk) thereof may be reduced.

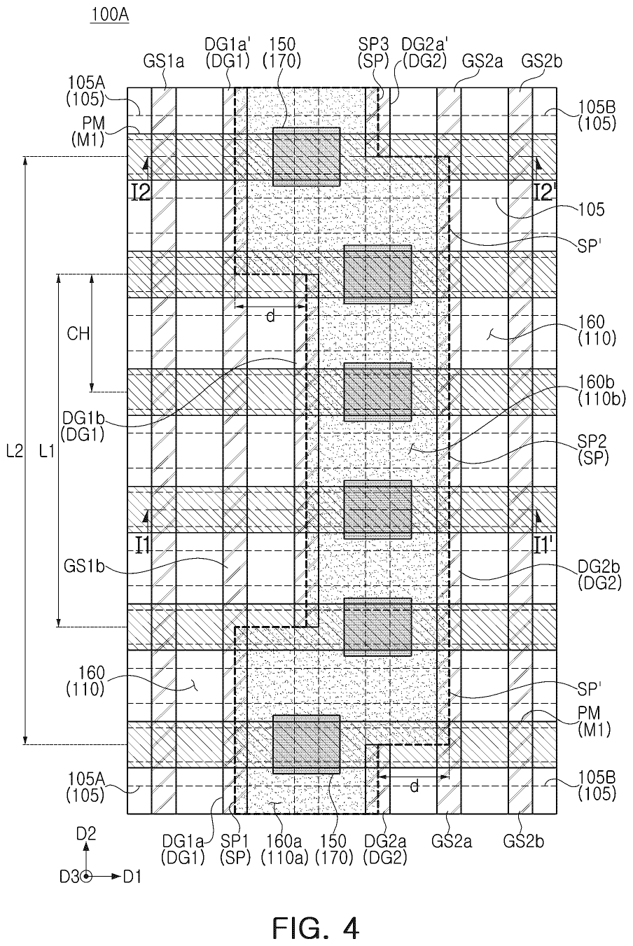

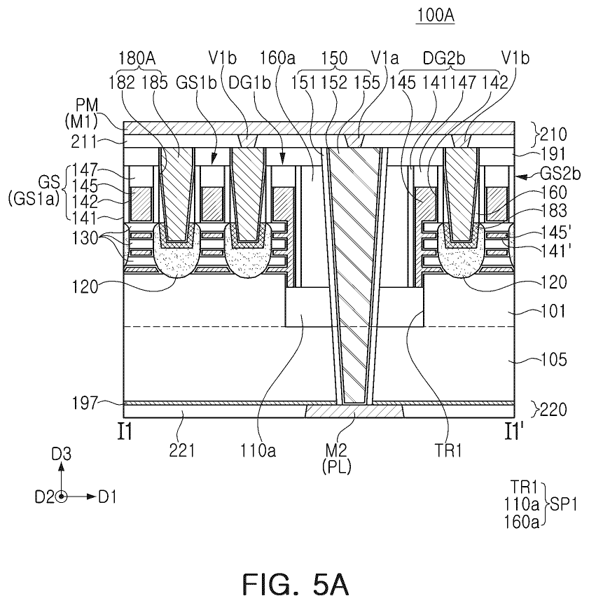

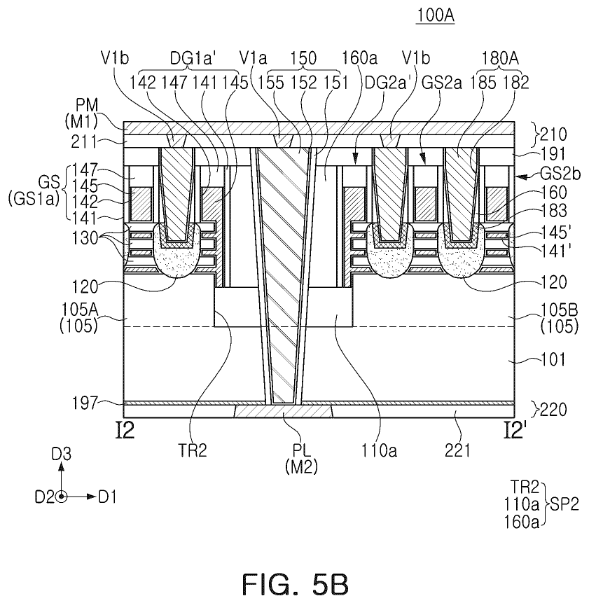

FIG. 4 is a plan view illustrating a semiconductor device according to an example embodiment, and FIGS. 5A and 5B are cross-sectional views of the semiconductor device illustrated in FIG. 4 taken along lines ‘I1-I1’ and ‘I2-I2’, respectively.

The semiconductor device 100A according to this example embodiment may be understood that it has a similar structure to the semiconductor device 100 illustrated in FIGS. 1 to 3B, except that the separation pattern SP has a zigzag pattern, the buried conductive structure 150 has a structure penetrating the substrate 101, and the power transmission line (PL) of the second interconnection structure 220 is directly connected to the buried conductive structure 150 with omitting the conductive through-structure 170. Additionally, unless otherwise stated, the components of this example embodiment may be understood with reference to descriptions of the same or similar components of the semiconductor device 100 illustrated in FIGS. 1 to 3B.

The separation pattern (SP) employed in this embodiment has a zigzag pattern. Referring to FIG. 4, similar to the previous example embodiment, the separation pattern (SP) may include a third separation pattern (SP3) connected to the second separation pattern (SP2) in a second direction (e.g., D2 direction), in addition to the first and second separation patterns SP1 and SP2 shifted in the first direction (e.g., D1 direction). The third separation pattern (SP3) is shifted in the first direction (e.g., D1 direction) so that a portion of the third separation pattern (SP3) overlaps with the second separation pattern (SP2), and may have a width in the first direction (e.g., D1 direction) that is the same as the width of the first separation pattern SP1 in the first direction (e.g., D1 direction). As illustrated in FIG. 4, the first and third separation patterns SP1 and SP3 may substantially completely overlap in the second direction (e.g., direction D2).

The second separation pattern SP2 is shifted by a distance d corresponding to the gate pitch P0 in the forward direction of the first direction (e.g., D1 direction) from the first separation pattern SP1, and the third separation pattern SP3 may be shifted by a distance d corresponding to the gate pitch P0 in the reverse direction of the first direction (e.g., D1 direction) from the second separation pattern SP2.

In this manner, the first and second dummy gate structures DG1 and DG2 located on both sides (i.e., first and second sides) of the zigzag shifted separation pattern SP are disconnected and each may have a shortened length corresponding to the shift cycle.

Referring to FIG. 4, the first dummy gate structure DG1 may be disconnected by being divided into a first dummy gate portion (DG1a) on the first side of the first separation pattern (SP1), a first dummy gate portion DG1b on the first side of the second separation pattern SP2, and a first dummy gate portion DG1a′ on the first side of the third separation pattern SP3. Similarly, the second dummy gate structure DG2 may be disconnected by being divided into a second dummy gate portion DG2a on the second side of the first separation pattern SP1, a second dummy gate portion DG2b on the second side of the second separation pattern SP2 and a second dummy gate portion DG2a′ on the second side of the third separation pattern SP3.

The first and second dummy gate structures DG1 and DG2 are formed along the ends of the first and second active patterns 105A and 105B, respectively, as illustrated in FIGS. 5A and 5B, and may thus have structurally unstable conditions unlike the first and second gate structures GS1 and GS2. In this example embodiment, the first and second dummy gate structures DG1 and DG2 are disconnected to have a shortened length by the zigzag separation pattern SP, and structural defects such as leaning defects may be significantly alleviated. In this example embodiment, the disconnected dummy gate structures may have different lengths. For example, the second dummy gate portion DG2b of the second separation patterns SP2 may have a length L2 greater than the length L1 of the first dummy gate portion DG1b. In each dummy gate portion (DG1a, DG1b′ DG1a′, DG2a, DG2b′ DG2a′), the length in the second direction (e.g., D2 direction) may be designed to be up to 2 to 6 cell heights (CH) (e.g., 3CH or 5CH). In some example embodiments, the length of each dummy gate portion DG1a, DG1b′DG1a′, DG2a, DG2b, an ‘DG2a’ may be 1 m or less (e.g., 900 nm or less).

The power transmission structure employed in this example embodiment may also have a structure different from that of the previous example embodiment.

The buried conductive structures 150 are arranged in a first direction within the separation pattern, similar to the previous example embodiment, and the arrangement of the buried conductive structures 150 may also be shifted in the first direction (e.g., D1 direction) similar to the shift of the first to third separation patterns SP1, SP2, and SP3. In this example embodiment, unlike the previous example embodiment, the conductive through-structure 170 is omitted, and the power transmission line PL of the second interconnection structure 220 may be directly connected to the buried conductive structure 150. The power transmission line PL may have a rail structure extending in one direction.

In some example embodiments, portions of the substrate 101 excluding the first and second active patterns 105A and 105B may be removed. For example, a portion of the substrate 101 may be removed using a polishing process until the lower surfaces of the first and second active patterns 105A and 105B and the lower surface of the device isolation layer 110 are exposed, and the second interconnection structure 220 may be formed directly on the removed surface. In this case, the buried conductive structures 150 may be connected to the power transmission line PL through the interlayer insulating layer 160 and the device isolation layer 110 and the substrate 101.

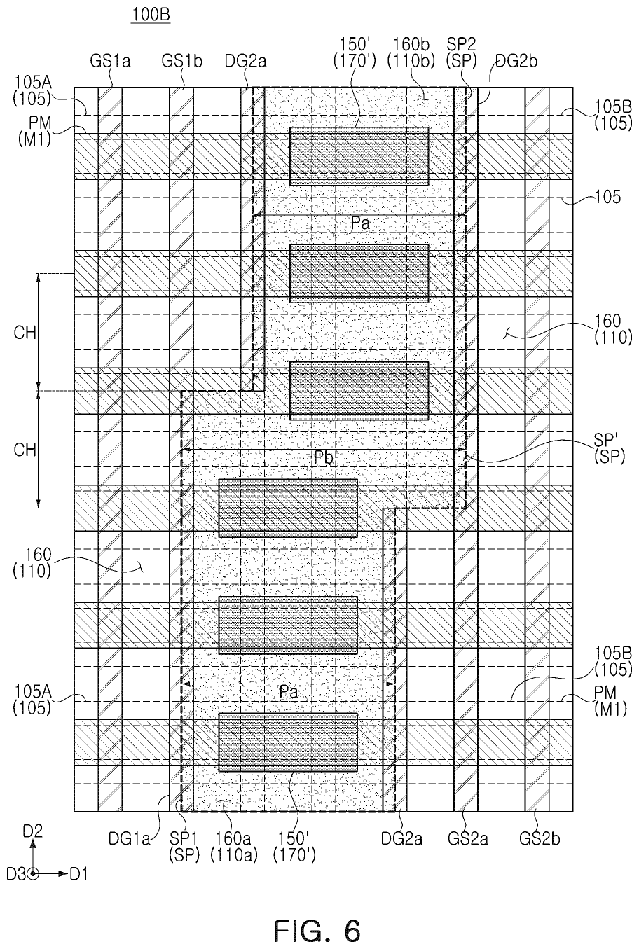

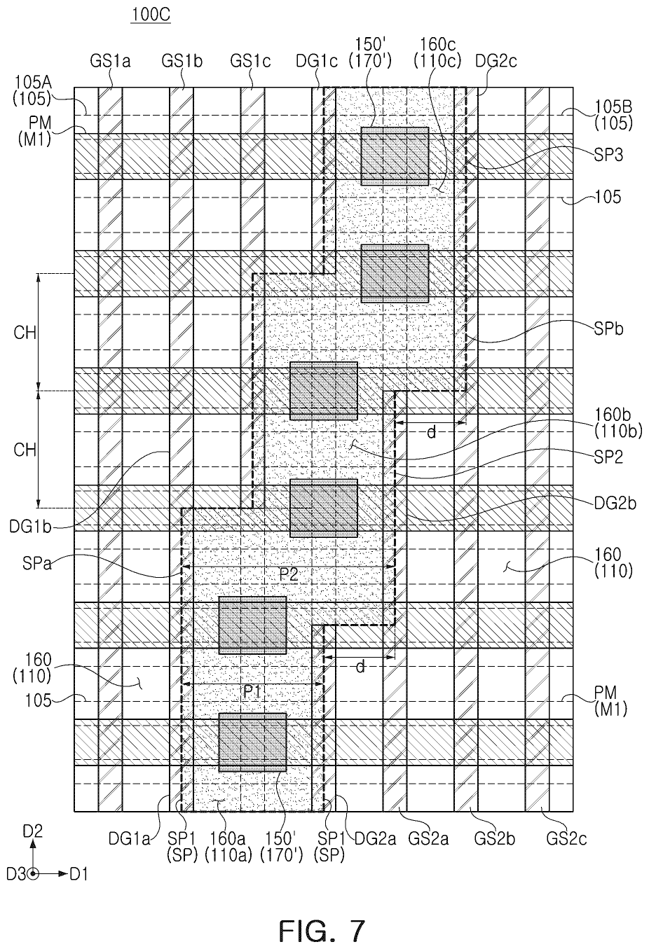

The partial shift of the separation pattern employed in this example embodiment may be implemented to have various patterns. For example, the width of the separation pattern may be adjusted (see FIG. 6), and the separation pattern may be shifted two or more times in the same first direction (e.g., forward direction) (see FIG. 7).

Referring to FIG. 6, the semiconductor device 100B according to this example embodiment may be understood that it has a similar structure to the semiconductor device 100 illustrated in FIGS. 1 to 3B, except that the separation pattern SP has a larger width than that of the previous example embodiment. Additionally, unless otherwise stated, the components of this example embodiment may be understood with reference to descriptions of the same or similar components of the semiconductor device 100 illustrated in FIGS. 1 to 3B.

The separation pattern (SP) employed in this example embodiment may have a larger width (Pa) than that of the previous example embodiment. In this example embodiment, the width Pa of each of the first and second separation patterns SP1 and SP2 may be three times the gate pitch P0. The first and second separation patterns SP1 and SP2 have the same width. In this example embodiment, the distance shifted from the first separation pattern SP1 to the first direction (e.g., D1 direction) of the second separation pattern SP2 may correspond to the gate pitch P0 and may be appropriately adjusted within a range smaller than the width (Pa) of the first and second separation patterns SP1 and SP2. For example, in this example embodiment, the second separation pattern SP2 may be shifted to twice the gate pitch.

The separation pattern SP may have a connection separation pattern SP′ provided as an area shifted between the first and second separation patterns SP1 and SP2. The connection separation pattern (SP′) may have a width that overlaps each of the first and second separation patterns SP1 and SP2 in a second direction (e.g., D2 direction) between the first and second separation patterns SP1 and SP2. The connection separation pattern SP′ may have a width (Pb) greater than the respective widths (Pa) of the first and second separation patterns. For example, the width Pb of the connection separation pattern SP′ may have a length obtained by adding the shifted distance d to the width Pa of the first and second separation patterns SP1 and SP2.

Referring to FIG. 7, the semiconductor device 100C according to this example embodiment may be understood as having a structure similar to the semiconductor device 100 illustrated in FIGS. 1 to 3B, except that the semiconductor device 100C has a separation pattern SP that is shifted in a different manner. Additionally, unless otherwise stated, the components of this example embodiment may be understood with reference to descriptions of the same or similar components of the semiconductor device 100 illustrated in FIGS. 1 to 3B.

The separation pattern (SP) employed in this example embodiment includes first to third separation patterns (SP1, SP2, SP3) similar to the separation pattern (SP) illustrated in FIG. 4 and has a pattern shifted in a different manner. The second separation pattern SP2 is shifted by a distance d corresponding to the gate pitch P0 in the forward direction of the first direction (e.g., D1 direction) from the first separation pattern SP1, and the third separation pattern SP3 may be shifted by a distance d corresponding to the gate pitch P0 in the same forward direction of the first direction (e.g., D1 direction) from the second separation pattern SP2.

In this example embodiment as well, the first and second dummy gate structures DG1 and DG2 located on both sides (i.e., the first side and the second side) of the separation pattern SP may be disconnected and have a shortened length corresponding to the shift period.

Referring to FIG. 7, the first dummy gate structure DG1 may be disconnected by being divided into a first dummy gate portion (DG1a) on the first side of the first separation pattern (SP1), a first dummy gate portion DG1b on the first side of the second separation pattern SP2, and a first dummy gate portion DG1c on the first side of the third separation pattern SP3. Similarly, the second dummy gate structure DG2 may be disconnected by being divided into a second dummy gate portion DG2a on the second side of the first separation pattern SP1, a second dummy gate portion DG2b on the second side of the second separation pattern SP2 and a second dummy gate portion DG2c on the second side of the third separation pattern SP3.

Accordingly, the first and second dummy gate structures DG1 and DG2 are disconnected to have a shortened length, thereby significantly reducing structural defects such as leaning defects. Each dummy gate portion (DG1a, DG1b, DG1c, DG2a, DG2b, DG2c) may be designed with a length in the second direction (e.g., D2 direction) of up to 2 to 6 cell heights (CH) (e.g., 2CH). In some example embodiments, the length of each dummy gate portion DG1a, DG1b, DG1c, DG2a, DG2b, and DG2c may be 1 m or less (e.g., 900 nm or less).

According to the above-described embodiment, the length of the first and second dummy gate structures DG1 and DG2 adjacent to the separation pattern SP is shortened by employing the separation pattern SP shifted in various manners, and thus, defects (e.g., lean risk) of the first and second dummy gate structures DG1 and DG2 may be improved.

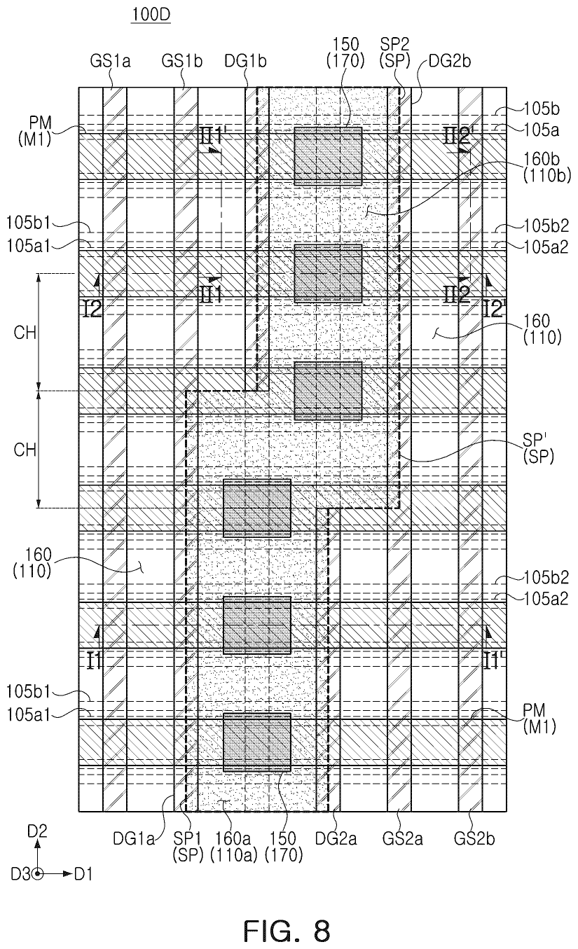

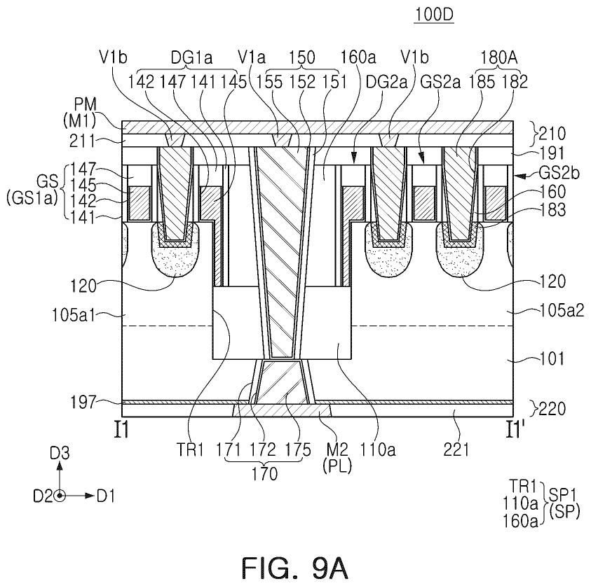

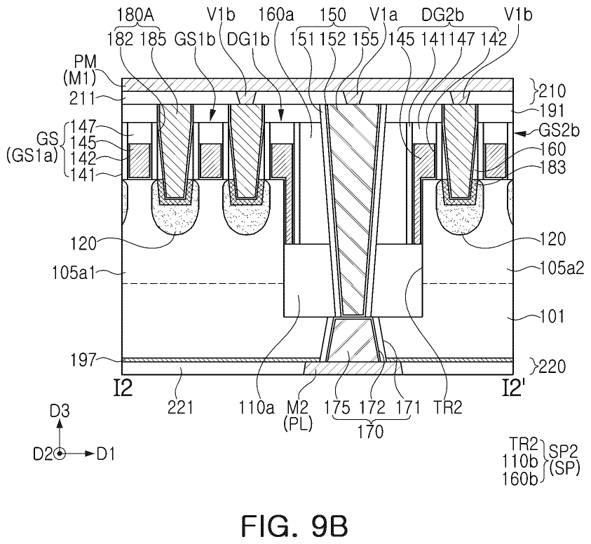

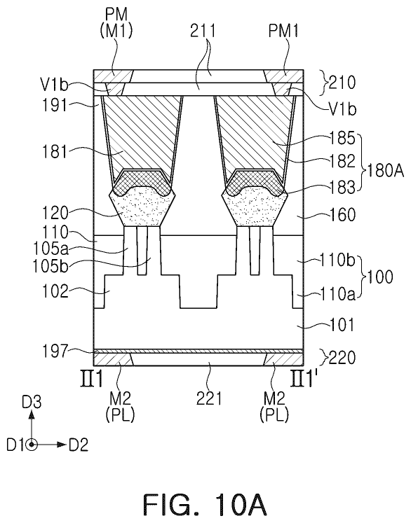

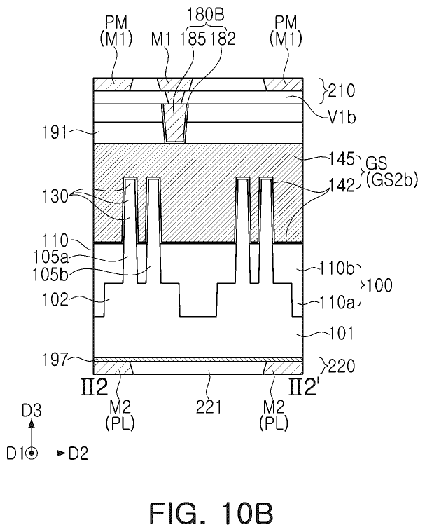

FIG. 8 is a plan view illustrating a semiconductor device according to an example embodiment, FIGS. 9A and 9B are cross-sectional views of the semiconductor device illustrated in FIG. 9 taken along lines ‘I1-I1’ and ‘I2-I2’, respectively, and FIGS. 10A and 10B are cross-sectional views of the semiconductor device illustrated in FIG. 9 taken along lines I′1-II1′ and I′2-II2′, respectively.

Referring to FIGS. 8, 9A, 9B, 10A and 10B, a semiconductor device 100D according to this example embodiment may be understood as similar to the semiconductor device 100 illustrated in FIGS. 1 to 3B, except that the channel structure is provided with a plurality of active pins (105a1, 105b1, and 105a2, 105b2). Additionally, unless otherwise stated, the components of this example embodiment may be understood with reference to descriptions of the same or similar components of the semiconductor device 100 illustrated in FIGS. 1 to 3B.

The channel structure employed in this example embodiment, unlike the multi-channel structure employed in the previous example embodiments, may include a corresponding pair of a first set of active pins 105a1 and 105b1 and a second set of active pins 105a2 and 105b2, respectively. The active pins 105A and 105B are illustrated as being provided in pairs, but are not limited thereto and may be provided singly or in a group of three or more.

Active pins 105a1, 105b1, and 105a2, 105b2, respectively, have a structure that extends in a first direction (e.g., D1 direction) on the substrate 101 and protrudes upward (e.g., D3 direction) from the active region 102. In this example embodiment, each of the active fins 105a1, 105b1, and 105a2, 105b2 may be a structure obtained by separating one fin structure by a separation pattern SP extending in a second direction (e.g., D2 direction).

The device isolation layer 110 may be disposed on the substrate 101 to define an active region 102 including active fins 105a1 and 105b1, and 105a2 and 105b2. For example, the device isolation layer 110 may include silicon oxide or a silicon oxide-based insulating material. The device isolation layer 110 may be divided into a first device isolation layer 110a defining the active region 102, and a second device isolation layer 110b defining the active fins 105a1 and 105b1, and 105a2 and 105b2 (see FIG. 10A and FIG. 10B). The first device isolation layer 110a may have a bottom surface deeper than that of the second device isolation layer 110b. For example, the first device isolation layer 110a is also called deep trench isolation (DTI), and the second device isolation layer 110b may also be referred to as shallow trench isolation (STI). In this example embodiment, the depth of the first and second trenches TR1 and TR2 of the separation pattern SP may be the same as the depth of the first device isolation layer 110a.

The separation pattern SP employed in this example embodiment may have a partially shifted pattern, similar to the example embodiment of FIG. 1. As illustrated in FIG. 8, the first dummy gate structure DG1 may be separated into a first dummy gate portion DG1a on the first side of the first separation pattern SP1 and a first dummy gate portion DG1b on the first side of the second separation pattern SP2. Similarly, the second dummy gate structure DG2 may be separated into a second dummy gate portion DG2a on the second side of the first separation pattern SP1 and a second dummy gate portion DG2b on the second side of the second separation pattern SP2. In this manner, the length of the first and second dummy gate structures DG1 and DG2 in the second direction (e.g., D2 direction) is shortened, and structural defects, such as the leaning defect described above, may be significantly alleviated.

The separation pattern SP may have a connection separation pattern SP′ provided as an area shifted between the first and second separation patterns SP1 and SP2. The connection separation pattern (SP′) may have a width that overlaps each of the first and second separation patterns SP1 and SP2 in a second direction (e.g., D2 direction) between the first and second separation patterns SP1 and SP2.

The semiconductor device 100D according to this example embodiment includes power transmission structures arranged in the separation pattern SP in a second direction (e.g., direction D2). Each of the power transmission structures employed in this example embodiment includes a buried conductive structure 150, and conductive through-structures 170 extending from the second side of the substrate 101 toward the first side and connected to the buried conductive structure 150.

FIGS. 8A and 8B, the buried conductive structures 150 extend to the first side of the substrate 101, and the power transmission structures 170 may penetrate the substrate 101 and contact the bottom surfaces of the buried conductive structures 150 on the first side of the substrate 101, respectively. Each of the conductive through-structures 170 receives power from the backside power line PL (or the second power line) located on the second side of the substrate 101 and supplies power to each logic cell through the buried conductive structures 150. Power may be supplied to the source/drain patterns 120. In this example embodiment, the buried conductive structures 150 may be electrically connected to the source/drain patterns 120 through the first power line (PM) of the first interconnection structure 210.

As set forth above, according to the above-described example embodiments, by shifting the separation pattern in which the power transmission structures are arranged by a constant width along with the power transmission structures, structural vulnerability (e.g., leaning risk) of the (dummy) gate structure adjacent to the separation pattern may be reduced.

While some example embodiments have been illustrated and described above, it will be apparent to those skilled in the art that modifications and variations could be made without departing from the scope of the present inventive concepts as defined by the appended claims.

What is claimed is:

1. A semiconductor device comprising:
a substrate having a first surface and a second surface opposing each other;
a plurality of active patterns respectively extending in a first direction on the first surface of the substrate;
a separation pattern extending in a second direction on the first surface of the substrate, the second direction intersecting the first direction, the separation pattern dividing each of the plurality of active patterns into first and second active patterns, the separation pattern including a first separation pattern and a second separation pattern shifted from the first separation pattern in the first direction to partially overlap the first separation pattern in the second direction;
a first dummy gate structure and a second dummy gate structure on both sides of the separation pattern, respectively, the first and second dummy gate structures extending along corresponding end portions of the first and second active patterns in the second direction, respectively;
a plurality of first gate structures and a plurality of second gate structures crossing the first and second active patterns, respectively, the first and second gate structures extending in the second direction;
source/drain patterns on both sides of each of the plurality of first and second gate structures and on the first and second active patterns;
an interlayer insulating layer on the substrate and covering the source/drain patterns;
a contact structure penetrating through the interlayer insulating layer and connected to at least one of the source/drain patterns;
a plurality of buried conductive structures in the separation pattern and arranged in the second direction, at least one of the plurality of buried conductive structures penetrating through the interlayer insulating layer and electrically connected to the contact structure; and
a plurality of conductive through-structures extending from the second surface of the substrate toward the first surface, the plurality of conductive through-structures connected to the plurality of buried conductive structures, respectively.

2. The semiconductor device of claim 1, wherein
the first dummy gate structure on a first side of the first separation pattern is connected to one of the plurality of first gate structures on the first side of the second separation pattern, and
the second dummy gate structure on a second side of the second separation pattern is connected to one of the plurality of second gate structures on the second side of the first separation pattern.

3. The semiconductor device of claim 1, wherein
the buried conductive structures include first buried conductive structures arranged in the second direction in the first separation pattern, and second buried conductive structures arranged in the second direction in the second separation pattern, and
an arrangement of the second buried conductive structures is shifted in the first direction from an arrangement of the first buried conductive structures.

4. The semiconductor device of claim 1, wherein
the plurality of first or second gate structures are arranged at a first pitch in the first direction, and
a shifted distance of the first and second separation patterns in the first direction is equal to the first pitch.

5. The semiconductor device of claim 4, wherein a width of each of the first and second separation patterns in the first direction is an integer multiple of the first pitch.

6. The semiconductor device of claim 4, wherein widths of the first and second separation patterns are same.

7. The semiconductor device of claim 1, wherein
a pitch of adjacent buried conductive structures among the plurality of buried conductive structures defines a cell height, and
a length of the first and second separation patterns in the second direction equals the cell height.

8. The semiconductor device of claim 7, wherein the length of each of the first and second separation patterns in the second direction is 1 m or less.

9. The semiconductor device of claim 1, wherein the separation pattern includes a connection separation pattern between the first and second separation patterns, the connection separation pattern having a width defined by a pitch between the first dummy gate structure of the first separation pattern and the second dummy gate structure of the second separation pattern.

10. The semiconductor device of claim 9, wherein a length of the connection separation pattern in the second direction is equal to a pitch of adjacent buried conductive structures between the first and second separation patterns.

11. The semiconductor device of claim 1, wherein the separation pattern includes a third separation pattern connected to the second separation pattern in the second direction, the third separation pattern shifted in the first direction to partially overlap the second separation pattern.

12. The semiconductor device of claim 11, wherein the third separation pattern has a width in the first direction equal to a width of the first separation pattern in the first direction and the third separation pattern overlaps the first separation pattern in the second direction.

13. The semiconductor device of claim 1, wherein
the semiconductor device includes a plurality of channel layers on a corresponding one of the first and second active patterns, the plurality of channel layers spaced apart from each other in a direction perpendicular to an upper surface of the substrate, and
the first and second gate structures each include a gate electrode surrounding the plurality of channel layers and extending in the second direction and a gate insulating film between the plurality of channel layers and the gate electrode.

14. The semiconductor device of claim 1, wherein the buried conductive structures extend to the first surface of the substrate, and the conductive through-structures each contact the buried conductive structure on the first surface of the substrate.

15. The semiconductor device of claim 1, wherein the buried conductive structures extend into the substrate, and the conductive through-structures each contact the buried conductive structure within the substrate.

16. A semiconductor device comprising:
a plurality of active patterns respectively extending on a substrate in a first direction;
a separation pattern extending on the substrate in a second direction, the second direction intersecting the first direction, the separation pattern dividing each of the plurality of active patterns into a first active pattern and a second active pattern, the separation pattern including a plurality of first separation patterns and a plurality of second separation patterns alternating with each other in the second direction, the plurality of second separation patterns being shifted from the plurality of first separation patterns in the first direction to partially overlap the plurality of first separation patterns in the second direction;
a first dummy gate structure and a second dummy gate structure on both sides of the separation pattern, respectively, the first and second dummy gate structures extending along corresponding end portions of the first and second active patterns in the second direction, respectively;
a plurality of first and second gate structures crossing the first and second active patterns, respectively, the first and second gate structures extending in the second direction;
source/drain patterns on both sides of each of the plurality of first and second gate structures and on the first and second active patterns;
an interlayer insulating layer on the substrate and covering the source/drain patterns;
a contact structure penetrating through the interlayer insulating layer and connected to at least one of the source/drain patterns;
a plurality of buried conductive structures in the separation pattern and arranged in the second direction, at least one of the plurality of buried conductive structures penetrating through the interlayer insulating layer and electrically connected to the contact structure;
a plurality of conductive through-structures extending from a lower surface of the substrate toward an upper surface of the substrate, the plurality of conductive through-structures connected to the plurality of buried conductive structures, respectively; and
a first interconnection structure on the interlayer insulating layer, the first interconnection structure including a first interconnection layer connecting the contact structure and the buried conductive structures.

17. The semiconductor device of claim 16, wherein
a width of each of the plurality of first and second separation patterns in the first direction is equal to an integer multiple of a pitch at which the plurality of first or second gate structures are arranged in the first direction, and
a length of each of the plurality of first and second separation patterns in the second direction is 1 m or less.

18. The semiconductor device of claim 16, wherein the separation pattern has a zigzag pattern in plan view.

19. The semiconductor device of claim 16, further comprising:
a second interconnection structure on a second surface of the substrate, the second interconnection structure including a second interconnection layer connected to a corresponding one of the conductive through-structures.

20. A semiconductor device comprising:
a plurality of active patterns respectively extending on a substrate in a first direction;
a separation pattern extending on the substrate in a second direction, the second direction intersecting the first direction, the separation pattern dividing each of the plurality of active patterns into a first active pattern and a second active pattern, the separation pattern including a plurality of first separation patterns and a plurality of second separation patterns alternating with each other in the second direction, the plurality of second separation patterns being shifted from the plurality of first separation patterns in the first direction to partially overlap the plurality of first separation patterns in the second direction;
a first dummy gate structure and a second dummy gate structure on first and second sides of the separation pattern, respectively, the first and second dummy gate structures extending along corresponding end portions of the first and second active patterns in the second direction, respectively; and
a plurality of first and second gate structures extending in the second direction and crossing the first and second active patterns, respectively,
wherein the first dummy gate structure on a first side of each of the plurality of first separation patterns is connected to a corresponding one of a plurality of first gate structures on a first side of adjacent second separation patterns among the plurality of second separation patterns, and
the second dummy gate structure on a second side of each of the plurality of second separation patterns is connected to a corresponding one of a plurality of second gate structures on a second side of adjacent first separation patterns among the plurality of first separation patterns.
